(19) United States
(12) Patent Application Publication
(10) Pub. No.: US 2025/0241159 A1
(43) Pub. Date: Jul. 24, 2025

(54) ARRAY SUBSTRATE AND PREPARATION METHOD THEREOF, DISPLAY PANEL, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Chi YU, Beijing (CN); Yao HUANG, Beijing (CN); Lili DU, Beijing (CN)

(21) Appl. No.: 18/704,434

(22) PCT Filed: Jun. 1, 2023
(86) PCT No.: PCT/CN2023/097766

§ 371 Date: Apr. 24, 2024

(30) Foreign Application Priority Data
Jun. 2, 2022 (CN) 202210624733.7

(51) Int. Cl. H10K 59/35; H10H 29/30; H10H 29/34; H10H 29/37; H10K 59/122; H10K 59/65

(52) U.S. Cl. CPC H10K 59/353; H10H 29/345; H10H 29/352; H10H 29/37; H10K 59/122; H10K 59/352; H10K 59/65

(57) ABSTRACT

A display panel is provided. The display panel includes a base substrate including a first display region, a second display region, and a transition region disposed between the first display region and the second display region; a first pixel unit disposed in the first display region, wherein the first pixel unit has a first aperture ratio; a second pixel unit disposed in the second display region, wherein the second pixel region has a second aperture ratio; and a third pixel unit disposed in the transition region, wherein the third pixel unit has a third aperture ratio; wherein the first aperture ratio is greater than the second aperture ratio; in a direction pointing from the first display region towards the second display region, the first aperture ratio, the third aperture ratio, and the second aperture ratio progressively decrease.

### CROSS-REFERENCE TO RELATED APPLICATIONS

This application is a U.S. national phase application based on PCT/CN2023/097766, filed on Jun. 1, 2023, which claims priority to Chinese patent application No. 202210624733.7, filed on Jun. 2, 2022, entitled “DISPLAY PANEL, METHOD OF PREPARATION THEREOF, AND DISPLAY DEVICE,” the content of which is incorporated herein by reference in its entirety.

### TECHNICAL FIELD

The present disclosure relates to an array substrate and a preparation method thereof, a display panel, and a display device.

### BACKGROUND

Full display with camera (FDC) is widely used in display devices to increase the screen-to-body ratio of the display devices. In the FDC, a camera is embedded in a display region of the display device. Moreover, for high transmittance of an under-display camera region and for further implementation of a camera function, the area of metal within the display region is usually minimized as much as possible.

### SUMMARY

Embodiments of the present disclosure provide an array substrate and a preparation method thereof, a display panel, and a display device. The technical solutions are as follows:

In a first aspect, the embodiments of the present disclosure provide an array substrate. The array substrate includes: a base substrate including a first display region, a second display region, and a transition region disposed between the first display region and the second display region; a first pixel unit disposed in the first display region, wherein the first pixel unit has a first aperture ratio; a second pixel unit disposed in the second display region, wherein the second pixel unit has a second aperture ratio; and a third pixel unit disposed in the transition region, wherein the third pixel unit has a third aperture ratio; wherein in a direction pointing from the first display region towards the second display region, the first aperture ratio, the third aperture ratio and the second aperture ratio progressively decrease.

In a second aspect, the embodiments of the present disclosure provide a display panel. The display panel includes: a cover plate, and any one of the array substrates according to the embodiments of the present disclosure, wherein a portion of the array substrate other than the base substrate is disposed between the cover plate and the base substrate.

In a third aspect, the embodiments of the present disclosure provide a display device. The display device includes: a power supply assembly, and any one of the display panels according to the embodiments of the present disclosure, wherein the power supply assembly is configured to supply power to the display panel.

In a fourth aspect, the embodiments of the present disclosure provide a method of preparing a display panel for preparing any one of the array substrates according to the embodiments of the present disclosure. The method includes: preparing the first pixel unit, the second pixel unit, and the third pixel unit on the base substrate; wherein the base substrate includes the first display region, the second display region, and the transition region disposed between the first display region and the second display region; the first pixel unit having the first aperture ratio is disposed in the first display region; the second pixel unit having the second aperture ratio is disposed in the second display region; the third pixel unit having the third aperture ratio is disposed in the transition region; and in the direction pointing from the first display region towards the second display region, the first aperture ratio, the third aperture ratio and the second aperture ratio progressively decrease.

### BRIEF DESCRIPTION OF DRAWINGS

FIG. 1 is a schematic diagram of a pixel arrangement scheme in the related art;

FIG. 2 is a schematic diagram of another pixel arrangement scheme in the related art;

FIG. 3 is a schematic diagram of one relative positional relationship of each display region and an aperture in a pixel defining layer in a display panel according to some embodiments of the present disclosure;

FIG. 4 is a schematic diagram of another relative positional relationship of each display region in a display panel according to some embodiments of the present disclosure;

FIG. 5 is a structural schematic diagram of a light-emitting device and a pixel defining layer in some embodiments of the present disclosure;

FIG. 6 is a schematic diagram of an aperture in a pixel defining layer in each display region in a display panel according to some embodiments of the present disclosure;

FIG. 7 is a schematic diagram of a distribution of each display region in some embodiments of the present disclosure;

FIG. 8 is a schematic diagram of another distribution of each display region in some embodiments of the present disclosure;

FIG. 9 is a structural schematic diagram of a third pixel unit in some embodiments of the present disclosure;

FIG. 10 is another structural schematic diagram of a third pixel unit in some embodiments of the present disclosure; and

FIG. 11 is a flow diagram of a method of preparing a display panel according to some embodiments of the present disclosure.

### DETAILED DESCRIPTION

Hereinafter, some exemplary embodiments are briefly described. As may be recognized by those skilled in the art, the described embodiments may be modified in a variety of different ways without departing from the spirit or scope of the present disclosure. Accordingly, the accompanying drawings and descriptions are considered to be essentially exemplary and not limiting.

It is understood by those skilled in the art that all terms used herein, including technical and scientific terms, unless otherwise defined, have the same meaning as is generally understood by those of ordinary skill in the art to which the present disclosure belongs. It should also be understood that terms such as those defined in general-purpose dictionaries are to be understood as having a meaning consistent with that in the context of some practices and are not to be construed in an idealized or overly formalized sense unless specifically defined as herein.

Several terms involved in the embodiments of the present disclosure are first described:

Full display with camera (FDC): refers to a technical design where a camera hole opened in a display screen for receiving a front camera is canceled, and instead the front camera is built-in under the display screen. FDC improves the screen-to-body ratio of the display device, and achieves the true full screen without holes compared to the notch screen, waterdrop screen, or the like on the market now.

Real RGB: is a traditional arrangement of sub-pixels, wherein a square pixel is evenly divided into three sub-pixels.

Sub-pixel rendering (SPR): is a new arrangement of sub-pixels, compared to real RGB.

The inventors of the present disclosure have found in their research that, in the related art, a light-emitting area of the display region is usually determined by the area of an aperture in a pixel defining layer corresponding to each sub-pixel in the display region, and the larger the area of the aperture in the pixel defining layer, the larger the light-emitting area of the display region.

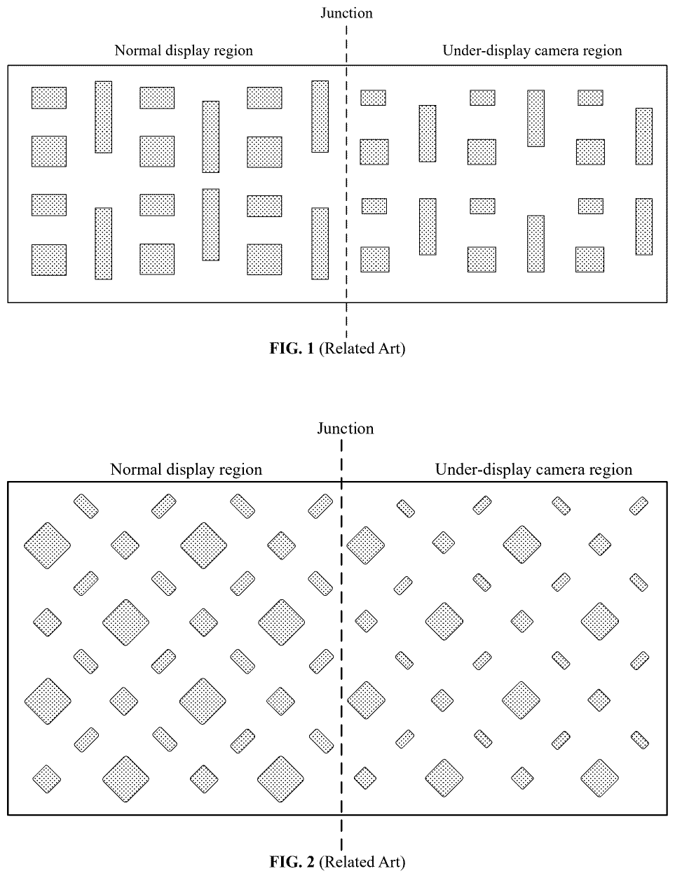

FIG. 1 illustrates a schematic diagram of apertures in a pixel defining layer in a normal display region and an under-display camera region in a traditional pixel arrangement scheme (real RGB). FIG. 2 illustrates a schematic diagram of apertures in a pixel defining layer in a normal display region and an under-display camera region in another magic pixel arrangement scheme (magic pixel). The magic pixel is an SPR algorithm pixel.

As can be seen from FIGS. 1 and 2, the area of each aperture in the pixel defining layer in the normal display region is larger than the area of the corresponding aperture in the under-display camera region, and thus a light-emitting area of the normal display region is larger than a light-emitting area of the under-display camera region, and there is a significant difference in the light-emitting area at a junction of the normal display region and the under-display camera region.

The technical solutions of the present disclosure and how the technical solutions of the present disclosure solve the above technical problems are described in detail hereinafter by way of specific embodiments.

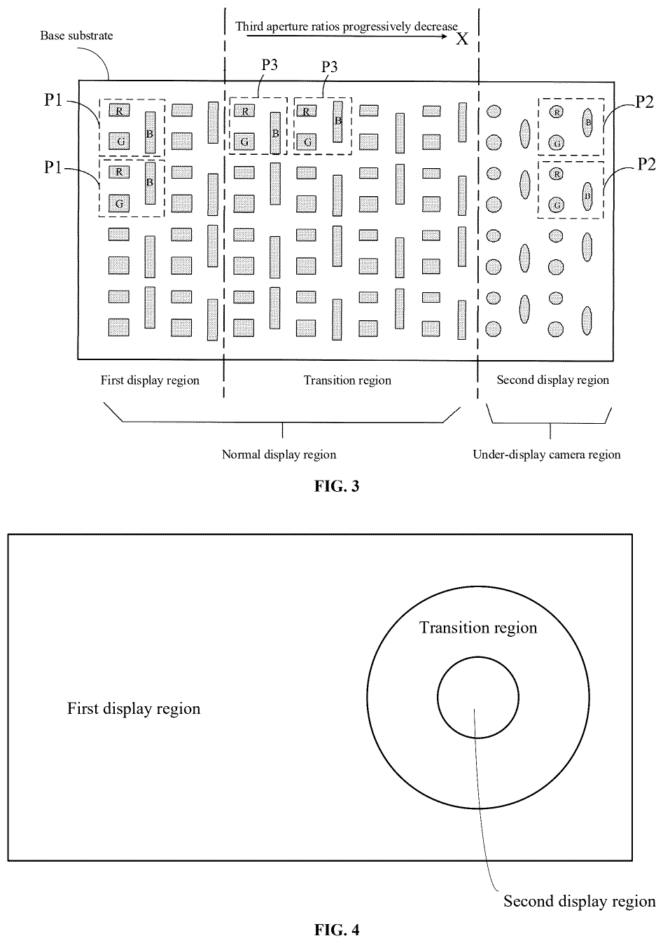

Some embodiments of the present disclosure provide an array substrate. As illustrated in FIG. 3, the array substrate includes a base substrate, a first pixel unit P1, a second pixel unit P2, and a third pixel unit P3. The base substrate includes a first display region, a second display region, and a transition region disposed between the first display region and the second display region. The first pixel unit P1 is disposed in the first display region and has a first aperture ratio; the second pixel unit P2 is disposed in the second display region and has a second aperture ratio; and the third pixel unit P3 is disposed in the transition region and has a third aperture ratio.

The first aperture ratio, the third aperture ratio, and the second aperture ratio progressively decrease in a direction pointing from the first display region towards the second display region.

Exemplarily, as illustrated in FIG. 3, an array substrate includes a base substrate, a plurality of first pixel units P1, a plurality of second pixel units P2, and a plurality of third pixel units P3. The plurality of first pixel units P1 are disposed in a first display region and have the same aperture ratio, i.e., a first aperture ratio, the plurality of second pixel units P2 are disposed in a second display region and have the same aperture ratio, i.e., a second aperture ratio, and the plurality of third pixel units P3 are disposed in a transition region. Third aperture ratios of the plurality of third pixel units P3 progressively decrease in the direction pointing from the first display region towards the second display region.

It is to be understood that the third aperture ratios of the plurality of third pixel units P3 may also not progressively decrease in the direction pointing from the first display region towards the second display region, for example, the third aperture ratios of the plurality of third pixel units P3 may also be constant or progressively increase in the direction pointing from the first display region towards the second display region. However, it should be noted that the third aperture ratios of the plurality of third pixel units P3 are all less than the first aperture ratio and are greater than the second aperture ratio.

The plurality of first pixel units P1 are arranged in the first display region, the plurality of second pixel units P2 are arranged in the second display region, and the plurality of third pixel units P3 are arranged in the transition region as examples in FIG. 3. It is understood that the number of first pixel units P1 in the first display region may also be 1, the number of second pixel units P2 in the second display region may also be 1, and the number of third pixel units P3 in the third display region may also be 1.

In the array substrate according to the embodiments of the present disclosure, the transition region is disposed between the first display region and the second display region. The aperture ratio of the first pixel unit of the first display region, the aperture ratio of the third pixel unit in the transition region, and the aperture ratio of the second pixel unit of the second display region progressively decrease. As a result, the transition of the aperture ratios from the first display region to the second display region is realized, thereby making the luminous brightness of the entire display region tends to change uniformly, weakening the boundary effect at junctions of different display regions.

In one example, as illustrated in FIG. 3, the second display region according to the embodiments of the present disclosure may be disposed on one side of the base substrate, and the transition region and the first display region are disposed sequentially on the other side of the base substrate. In another example, as illustrated in FIG. 4, the second display region may be disposed in a middle region of the base substrate, the transition region surrounds the second display region, and the first display region surrounds the transition region.

In the embodiments of the present disclosure, shapes of the first display region, the transition region, and the second display region may be defined according to actual needs. For example, the first display region, the transition region, and the second display region may all be rectangular as illustrated in FIG. 3; or the second display region may be circular as illustrated in FIG. 4, and the transition region may be ring-shaped as illustrated in FIG. 4.

A pixel density of the first display region may be greater than a pixel density of the second display region, or may be equal to the pixel density of the second display region. In the case where the pixel density of the first display region is greater than the pixel density of the second display region, a pixel density of the transition region may be equal to the pixel density of the first display region, or may be equal to the pixel density of the second display region, or may be less than the pixel density of the first display region and greater than the pixel density of the second display region.

In some embodiments, the array substrate according to the embodiments of the present disclosure further includes a pixel defining layer disposed in the first display region, the second display region, and the transition region.

The pixel defining layer of the first display region is provided with the apertures corresponding to a plurality of first pixel units P1. The pixel defining layer of the second display region is provided with the apertures corresponding to a plurality of second pixel units P2, and the pixel defining layer of the transition region is provided with the apertures corresponding to a plurality of third pixel units P3. An orthographic projection of the aperture in the pixel defining layer corresponding to any one of the pixel units on the base substrate is disposed within an orthographic projection of the any one of the pixel units on the base substrate. The pixel unit emits light in a region where the corresponding aperture is disposed.

Referring to the example of FIG. 3, the area of the aperture corresponding to the first pixel unit P1, the area of the aperture corresponding to the third pixel unit P3, and the area of the aperture corresponding to the second pixel unit P2 progressively decrease in the direction pointing from the first display region towards the second display region, such that the first aperture ratio, the third aperture ratio, and the second aperture ratio progressively decrease. For example, the areas of the apertures corresponding to the plurality of third pixel units P3 progressively decrease in the direction pointing from the first display region towards the second display region, such that the third aperture ratios of the plurality of third pixel units progressively decrease.

Referring to the example of FIG. 3, the first pixel unit P1, the second pixel unit P2, and the third pixel unit P3 may all include at least one sub-pixel in the embodiments of the present disclosure. An aperture in the pixel defining layer corresponding to each sub-pixel in the first pixel unit P1 is an aperture in the pixel defining layer corresponding to the first pixel unit P1, and a ratio of the area of the aperture to the area of the first pixel unit P1 is the first aperture ratio. An aperture in the pixel defining layer corresponding to each sub-pixel in the second pixel unit P2 is an aperture in the pixel defining layer corresponding to the second pixel unit P2, and a ratio of the area of the aperture to the area of the second pixel unit P2 is the second aperture ratio. An aperture in the pixel defining layer corresponding to each sub-pixel in the third pixel unit P3 is an aperture in the pixel defining layer corresponding to the third pixel unit P3, and a ratio of the area of the aperture to the area of the third pixel unit P3 is the third aperture ratio.

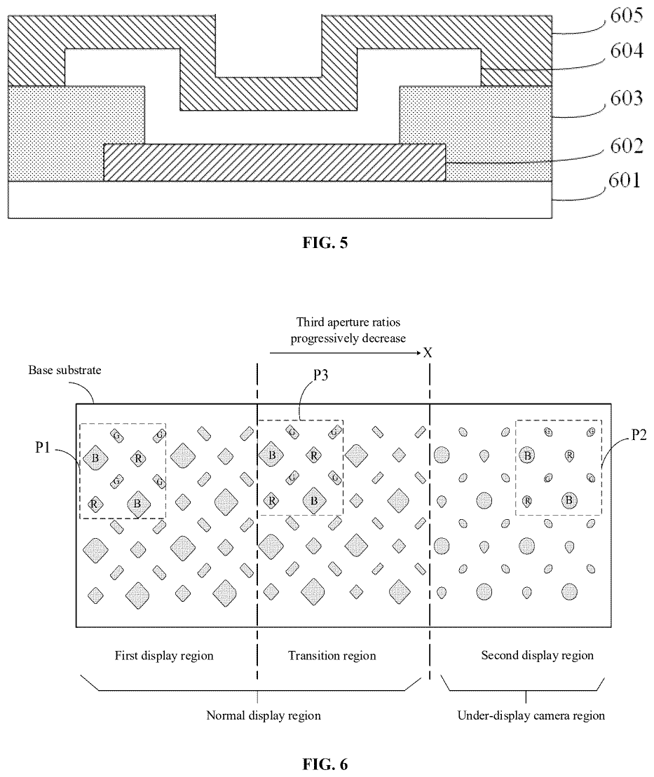

In the embodiments of the present disclosure, the sub-pixel may include a light-emitting device. The light-emitting device may include an anode, a light-emitting layer, and a cathode. A relationship between the light-emitting device, the pixel defining layer, and the aperture is illustrated in FIG. 5, wherein an anode 602 is disposed on a base substrate 601, a pixel defining layer 603 is disposed on a side, away from the base substrate 601, of the anode 602, a light-emitting layer 604 is disposed on a side, away from the base substrate 601, of the pixel defining layer 603, a cathode 605 is disposed on a side, away from the base substrate 601, of the light-emitting layer 604. The anode 602, the light-emitting layer 604, and the cathode 605 are sequentially arranged in a direction away from the base substrate 601. The pixel defining layer 603 is provided with the apertures corresponding to the sub-pixels, each aperture exposes a portion of an anode in one of the sub-pixels, and a portion of the light-emitting layer 604 fills the aperture in contact with the exposed portion of the anode. The pixel defining layer 603 is disposed between the anode 602 and the light-emitting layer 604.

In the embodiments of the present disclosure, the area of the aperture may be represented by the area of the orthographic projection of the aperture on the base substrate.

The above light-emitting layer may be an organic light-emitting layer. The anode, the organic light-emitting layer, and the cathode may form an organic light-emitting display (OLED) device or a light-emitting display (LED) device as a light-emitting device for the sub-pixel. The above light-emitting layer may also be an inorganic light-emitting layer, which is not limited in the embodiments of the present disclosure.

In the case where the area of each pixel unit is fixed, the first aperture ratio can be made greater than the second aperture ratio by making the area of the aperture corresponding to the first pixel unit P1 greater than the area of the aperture corresponding to the second pixel unit P2. The third aperture ratios of the plurality of third pixel units P3 may be made to progressively decrease by making the areas of the apertures corresponding to the plurality of third pixel units P3 progressively decrease.

The embodiments of the present disclosure may be applicable to a variety of pixel arrangement schemes, such as Real RGB and Magic pixel schemes. FIG. 3 illustrates a schematic diagram of the apertures in the pixel defining layer in the first display region, the transition region, and the second display region in the Real RGB scheme of the embodiments of the present disclosure. FIG. 6 illustrates a schematic diagram of apertures in a pixel defining layer in the first display region, the transition region, and the second display region in the Magic pixel arrangement scheme.

As can be seen from FIGS. 3 and 6, the area of an aperture in the pixel defining layer corresponding to each sub-pixel in the first display region is greater than the area of an aperture corresponding to a similar sub-pixel of the pixel defining layer in the second display region. The similar sub-pixel refers to the sub-pixels with the same color. For example, the area of the aperture in the pixel defining layer corresponding to a sub-pixel R (the sub-pixel emitting red light) in the first display region is greater than the area of the aperture in the pixel defining layer corresponding to the sub-pixel R at a corresponding position in the second display region. In a horizontal direction in FIG. 6, the areas of the apertures in the pixel defining layer corresponding to the sub-pixels R in the transition region progressively decrease. The size relationship of the areas of the apertures corresponding to sub-pixels other than the sub-pixel R (e.g., sub-pixel G or sub-pixel B) is the same.

In the embodiments of the present disclosure, a specific spacing needs to be maintained between the apertures corresponding to two adjacent sub-pixels to reduce the risk of color mixing between different sub-pixels. A value of the spacing may be set according to the actual needs.

In some embodiments, as illustrated in FIGS. 3 and 6, the first display region and the transition region belong to the normal display region, and the second display region belongs to the under-display camera region. Based on the embodiment, the transition region may be provided in the normal display region, such that the third aperture ratio of the transition region progressively approaches the second aperture ratio from a value close to the first aperture ratio. For example, in the case that the first aperture ratio is 1 and the second aperture ratio is 0.5, the third aperture ratio may progressively decrease from a value close to 1 to a value close to 0.5 in the X direction in FIGS. 3 and 6.

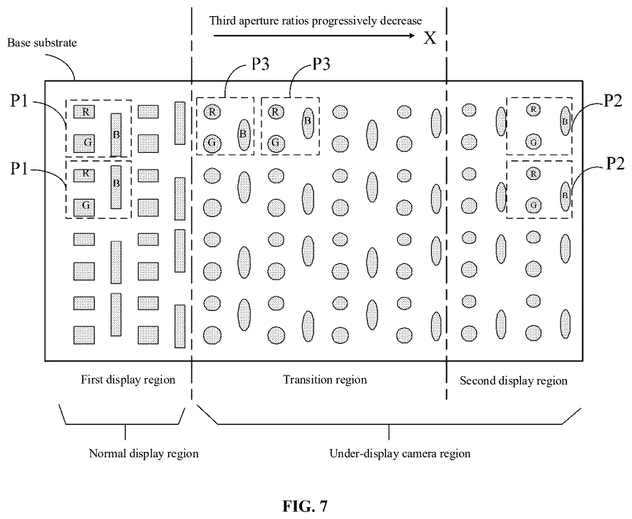

In some embodiments, as illustrated in FIG. 7, a first display region is a normal display region, and a second display region and a transition region are an under-display camera region. Based on the embodiment, the transition region may be arranged in the under-display camera region, such that a third aperture ratio of the transition region progressively approaches the first aperture ratio from a value close to the second aperture ratio. For example, in the case that the first aperture ratio is 1 and the second aperture ratio is 0.5, the third aperture ratio may progressively increase from 0.5 to a value close to 1 in the X direction in FIG. 7.

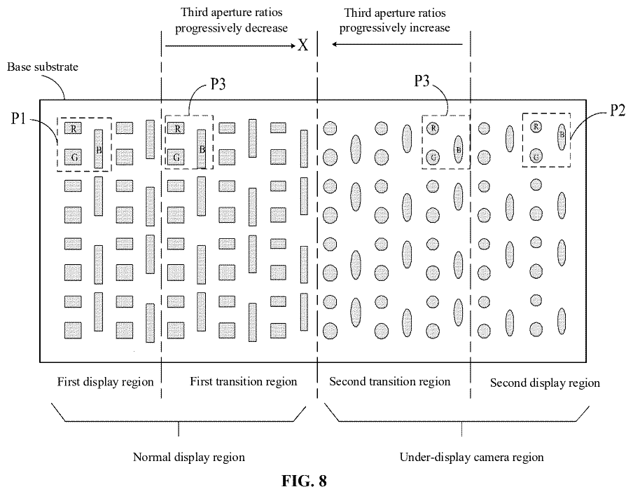

In some embodiments, as illustrated in FIG. 8, a transition region includes a first transition region and a second transition region. The first display region and the first transition region belong to a normal display region, and the second display region and the second transition region belong to an under-display camera region. Based on the embodiments, the transition region may be defined across regions, i.e., one portion is defined in the normal display region and the other portion is defined in the under-display camera region. A third aperture ratio of a third pixel unit P3 in the one portion progressively approaches a second aperture ratio from a value close to a first aperture ratio, and the aperture ratio of the third pixel unit P3 in the other portion progressively approaches the first aperture ratio from a value close to the second aperture ratio. For example, in the case that the first aperture ratio is 1 and the second aperture ratio is 0.5, in the X direction in FIG. 8, the third aperture ratio of the first transition region may progressively decrease from a value close to 1, and in an opposite direction of the X direction in FIG. 8, the third aperture ratio of the second transition region may progressively increase from a value close to 0.5. In this way, the aperture ratios on both sides of a junction between the normal display region and the under-display camera region is a value between 0.5 and 1.

In the embodiments of the present disclosure, the under-display camera region is a display region configured to be matched with the under-display camera device. In the case that the array substrate is applied to an electronic device such as a cell phone, a watch, or the like, the under-display camera device is provided in a position corresponding to the under-display camera region. The normal display region is a display region other than the under-display camera region. In the case that the array substrate is applied to an electronic device such as a cell phone, a watch, and the like, the under-display camera device is not provided in the position corresponding to the normal display region.

In some embodiments, a pixel defining layer with an aperture is arranged in a normal display region, wherein the aperture in the pixel defining layer has a polygonal shape.

The aperture in the embodiments of the present disclosure may be in the shape of an orthographic projection of the aperture on the base substrate.

Referring to the embodiments of FIGS. 3 and 7, the aperture in the pixel defining layer in the normal display region is quadrilateral, and in other embodiments, the apertures in the pixel defining layers in the normal display regions may be a pentagonal, hexagonal, trapezoidal, rhombic, proximately rectangular (e.g., a rounded rectangle, but not limited to this), and other shapes, which are conducive to increasing the aperture ratio.

Referring to the embodiment of FIG. 6, the aperture in the pixel defining layer in the normal display region may be a rectangle with chamfers, and the chamfers of different sub-pixels may be arranged in different directions.

In some embodiments, a pixel defining layer with an aperture is provided in the under-display camera region, wherein the aperture in the pixel defining layer has a circular shape or an oval shape.

Referring to the embodiments of FIGS. 3, 7, and 8, the apertures in the pixel defining layer in the under-display camera region are circular or elliptical, wherein the apertures corresponding to the sub-pixels R and G are circular, and the apertures corresponding to the sub-pixel B are elliptical. Such shapes have fewer prongs, which reduces diffraction and reduces the impact on the camera function of the under-display camera device.

In some embodiments, a pixel defining layer with apertures is provided in the under-display camera region, wherein at least a portion of the apertures in the pixel defining layer is shaped in the form of a waterdrop.

Referring to the embodiment of FIG. 6, the aperture in the pixel defining layer corresponding to the sub-pixel R in the under-display camera region is in the waterdrop shape. The waterdrop-shaped aperture facilitates the reduction of the metal share and the increase of the transmittance rate while keeping the aperture ratio constant, such that the transmittance effect required for the camera function is improved while the light-emitting effect is ensured.

In some embodiments, a third pixel unit P3 includes at least one sub-pixel; and an array substrate includes a plurality of third pixel units P3 distributed in an array in the transition region.

In one example, a third pixel unit P3 may include three sub-pixels. Referring to FIGS. 3, 7, and 8, the three sub-pixels are R, G, and B. The third pixel unit P3 composed of the three sub-pixels may be used as a base unit, a change rule of an aperture ratio among the base units is designed, and the aperture ratio of each sub-pixel within the base unit may be the same.

In the embodiments of the present disclosure, an aperture ratio of a sub-pixel is a ratio of an area of an aperture in a pixel defining layer corresponding to the sub-pixel to an area of the sub-pixel.

In another example, a third pixel unit P3 may include eight sub-pixels. Referring to FIG. 6, the eight sub-pixels specifically include two sub-pixels R, two sub-pixels B, and four sub-pixels G. The third pixel unit P3 composed of the eight sub-pixels may be used as a base unit, a change rule of an aperture ratio among the base units may be designed, and the aperture ratio of each sub-pixel within the base unit may be the same.

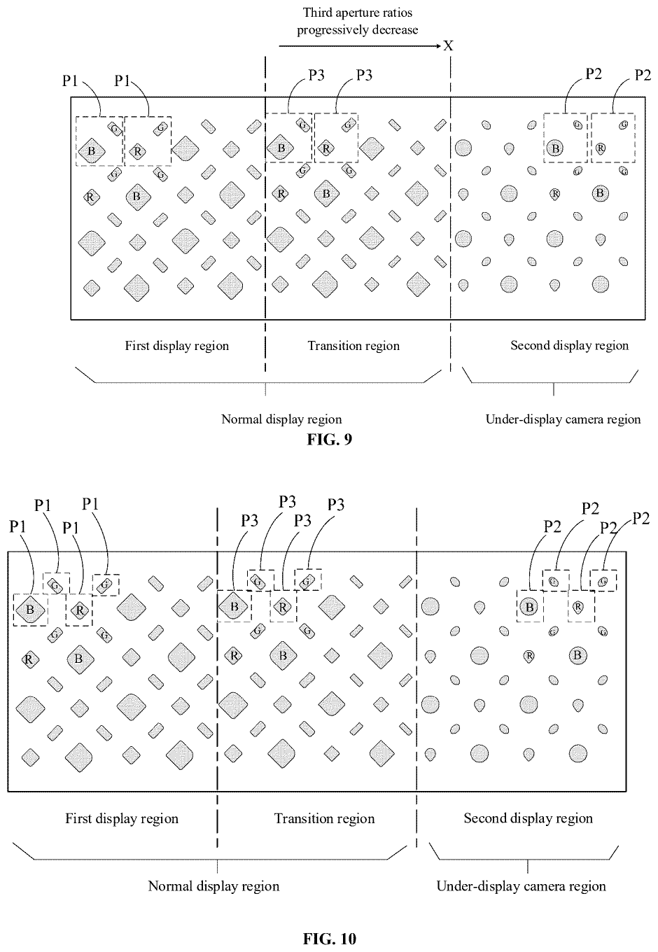

In yet another example, a third pixel unit P3 may include two sub-pixels, and types of the sub-pixels included in the two adjacent third pixel units P3 may be different. Referring to FIG. 9, the first third pixel unit P3 may include one sub-pixel B and one sub-pixel G, and the adjacent third pixel unit P3 on a right side may include one sub-pixel R and one sub-pixel G. The third pixel unit P3 composed of the two sub-pixels as a base unit, a change rule of an aperture ratio among each base unit is designed, and the aperture ratios of the sub-pixels within the base unit may be equal. A first pixel unit P1 and a second pixel unit P2 may also be divided in the same manner.

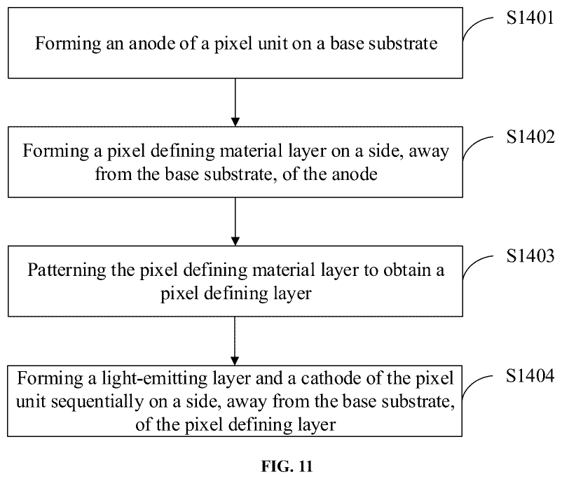

In yet another example, a third pixel unit P3 may include one sub-pixel, and types of the sub-pixels included in the two adjacent third pixel units P3 may be different. Referring to FIG. 10, one sub-pixel in the first four third pixel units P3, from left to right, is a sub-pixel B, a sub-pixel G, a sub-pixel R, and a sub-pixel G, respectively, i.e., each of the sub-pixels may be used as a base unit for designing a change rule of an aperture ratio among each sub-pixel. A first pixel unit P1 and a second pixel unit P2 may be divided in the same manner.

Based on each of the above examples, the array substrate according to the embodiments of the present disclosure is designed with different third pixel units P3 as a base unit for a change of the aperture ratio according to the actual needs to satisfy changes of different aperture ratios.

In some embodiments, a third pixel unit P3 includes a plurality of sub-pixels. The aperture ratios of the sub-pixels in the third pixel unit P3 progressively decrease in the direction pointing from the first display region towards the second display region.

FIGS. 3, 6, 7, 8, 9 to 10 all illustrate a case in which the third pixel unit P3 includes a plurality of sub-pixels, in which, in addition to the gradual change of the aperture ratio of the third pixel unit P3 as a base unit, the aperture ratio of each sub-pixel inside the third pixel unit is made to progressively decrease along the X direction, such that it is a simultaneous decrease in both outside and inside the base unit, and internally a finer change of the aperture ratio can be realized in the interior.

In some embodiments, the plurality of third pixel units are distributed in an array in the transition region. It is understood that the plurality of third pixel units may not be distributed in an array, which is not limited by the present disclosure.

Where the plurality of third pixel units are distributed in an array in the transition region, the row direction of the plurality of third pixel units is parallel to the direction pointing from the first display region towards the second display region, and the column direction of the plurality of third pixel units is perpendicular to the direction pointing from the first display region towards the second display region.

In some embodiments, the rate of change corresponding to any column of the third pixel units is less than or equal to 0.2. The rate of change corresponding to any column of the third pixel units is: the difference between the aperture ratio of the adjacent column of the pixel units and the aperture ratio of the any column of the third pixel units. The adjacent column of the pixel units is adjacent to the any column of the third pixel units. The adjacent column of the pixel units and the any column of the third pixel units are sequentially arranged in the direction pointing from the first display region towards the second display region.

In one example, the third aperture ratio of each column of the third pixel units may vary in the direction pointing from the first display region towards the second display region according to any one of the following rules:
0.8, 0.6, . . . , in this case, the rate of change corresponding to any column of the third pixel units is 0.2;
0.9, 0.8, . . . , in this case, the rate of change corresponding to any column of the third pixel units is 0.1;
0.95, 0.9, 0.85, . . . , in this case, the rate of change corresponding to any column of the third pixel units is 0.05.

In some embodiments, in the direction pointing from the first display region towards the second display region, a size of the transition region is matched with a predetermined range of change and step of change of the third aperture ratio.

In some examples, in the case that the second aperture ratio, the plurality of third aperture ratios vary (decrease) in a range of 1 to 0.5, and the rate of change corresponding to any column of the third pixel units is 0.1, then the size of the transition region is the size of 5 third pixel units P3. In the case that the second aperture ratio, the plurality of third aperture ratios vary (decrease) in a range of 1 to 0.5, and the rate of change corresponding to any column of the third pixel units is 0.05, then the size of the transition region is the size of 10 third pixel units P3.

In some embodiments, the foregoing embodiments are exemplified by the fact that different columns of the third pixel units correspond to the same rate of change, and it is to be understood that at least two columns of the third pixel units of the plurality of third pixel units correspond to different rate of changes.

In one example, the rate of changes of corresponding to a plurality of columns of the third pixel units may be the same, such as the rate of changes of corresponding to the plurality of columns of the third pixel units are all 0.2. In the case that the first aperture ratio is 1, the third aperture ratios of the plurality of columns of the third pixel units may be: 0.8, 0.6 . . . . In another example, the rate of changes of corresponding to a plurality of columns of the third pixel units may be different, for example, in the case that the first aperture ratio is 1, the third aperture ratios of the plurality of columns of the third pixel units may be: 0.9, 0.7 . . . , i.e., the rate of change corresponding to the first column of the third pixel units is 0.1 and the rate of change corresponding to the second column of the third pixel units is 0.2.

Based on the same inventive concept, the embodiments of the present disclosure provide a method of preparing an array substrate. As illustrated in FIG. 11, the method includes the following steps.

S1401, an anode of a pixel unit is formed on a base substrate.

S1402, a pixel defining material layer is formed on a side, away from the base substrate, of the anode.

S1403, the pixel defining material layer is patterned to obtain a pixel defining layer.

S1404, a light-emitting layer and a cathode of the pixel unit are formed sequentially on a side, away from the base substrate, of the pixel defining layer.

A material of the pixel defining material layer may be any one or more of: polyimide, silicon oxide, silicon nitride, or photoresist material.

In the embodiments of the present disclosure, the pixel defining material layer may be patterned by electron beam exposure, vaporization, or the like.

In patterning by electron beam exposure, a photoresist may be coated on the pixel defining material layer, and then exposure and development may be performed based on a predesigned pattern, an exposure region corresponds to a position where an aperture is to be formed, such that the pixel defining layer may be obtained.

In patterning by vaporization, a mask plate may be prepared in advance, and then the pixel defining layer may be obtained by vaporization based on the mask plate.

The array substrate prepared by the preparation method is referred to the array substrate in the preceding embodiments, which are not described herein.

In the preparation method, the first pixel unit, the second pixel unit, and the third pixel unit need to be prepared on the base substrate. In the preparation method, the pixel defining material layer may also be formed on the base substrate and be patterned to obtain the pixel defining layer. In the embodiments as illustrated in FIG. 11, for example, the pixel defining layer is prepared after the anode is formed and before the light-emitting layer is formed.

Based on the same inventive concept, the embodiments of the present disclosure also provide a display panel and a display device. The display panel includes a cover plate and any one of the array substrates according to the embodiments of the present disclosure. A structure in the array substrate other than the base substrate is disposed between the cover plate and the base substrate. The display device includes a power supply assembly and the display panel according to any of the embodiments of the present disclosure. The power supply assembly is configured to supply power to the display panel.

The display device according to the embodiments of the present disclosure may be a liquid crystal display device or an organic light-emitting diode display device. The display device may be any product or component with a display function, such as a liquid crystal display, a liquid crystal television, a digital photo frame, a cell phone or a tablet computer, and the like.

In the description of the specification, reference to the terms “an embodiment,” “some embodiments,” “examples,” “specific examples,” or “some examples,” means that the specific features, structures, materials, or characteristics described in conjunction with the embodiments or examples are included in at least one embodiment or example of the present disclosure. Moreover, the specific features, structures, materials, or characteristics described may be combined in any one or more of the embodiments or examples in a suitable manner. Moreover, without contradicting each other, those skilled in the art may combine and mix different embodiments or examples and features of different embodiments or examples described herein.

Furthermore, the terms “first” and “second” are used for descriptive purposes only and are not to be understood as indicating or implying relative importance or implicitly specifying the number of technical features indicated. Thus, a feature defined with the terms “first” and “second” may expressly or impliedly include at least one such feature. In the description of the present disclosure, “more than one” means two or more, unless otherwise expressly and specifically limited.

It should be further understood that the term “include” as used in the specification of the present disclosure refers to the features, integers, steps, operations, elements and/or components described herein, but does not preclude the presence or addition of one or more other features, integers, steps, operations, elements, components, and/or groups thereof. The term “and/or” as used herein includes all or any of the units and all combinations of one or more associated listings.

It is understood by those skilled in the art that steps, measures, and solutions in the various operations, methods, and processes already discussed in the present disclosure may be alternated, altered, combined, or deleted. Further, other steps, measures, and solutions in the various operations, methods, and processes already discussed in the present disclosure may also be alternated, altered, rearranged, disassembled, combined, or deleted. Further, in the related art, the steps, measures, and solutions in the various operations, methods, processes already disclosed in the present disclosure may also be alternated, altered, rearranged, decomposed, combined, or deleted.

It should be understood that although the steps in the flowchart of the accompanying drawings are indicated sequentially by the arrows, the steps are not necessarily executed sequentially in the order indicated by the arrows. Unless expressly stated herein, the execution of these steps is not strictly limited in order, and they may be executed in other orders. Moreover, at least a portion of the steps in the flowchart of the accompanying drawings may include a plurality of sub-steps or a plurality of phases. The plurality of sub-steps or the plurality of phases not necessarily executed to be completed at the same time, but may be executed at different time. The order of the plurality of sub-steps or the plurality of phases is not necessarily executed sequentially, but may be executed in turn or alternately with at least a portion of the other steps or sub-steps or phases of the other steps.

In the specification, the terms “center,” “longitudinal,” “transverse,” “length,” “width,” “thickness,” “up,” “down,” “front,” “back,” “left,” “right,” “vertical,” “horizontal,” “top,” “bottom,” “inside,” “outside,” “clockwise,” “counterclockwise,” “axial,” “radial,” “circumferential,” and the like indicate orientations or positional relationships based on those shown in the accompanying drawings, and are intended only to facilitate the description of the present disclosure and to simplify the description, and are not intended to indicate or imply that the device or element referred to must have a particular orientation, be constructed and operated in a particular orientation, and therefore are not to be construed as a limitation of the present disclosure.

In the specification, unless otherwise expressly stated and defined, a first feature “on” or “under” a second feature may include the first feature and the second feature being in direct contact, or the first feature and the second feature not being in direct contact, but being in contact with each other via another feature between them. Furthermore, the first feature “above,” “over,” and “on” the second feature may include the first feature being directly above and diagonally above the second feature, or simply indicating that the first feature is horizontally higher than the second feature. The first feature “below,” “down,” and “under” the second feature may include the first feature being directly below and diagonally below the second feature, or simply indicating that the first feature is horizontally lower than the second feature.

Described above are merely some exemplary embodiments of the present disclosure, but the scope of protection of the present disclosure is not limited thereto, and any person skilled in the art easily think of variations or substitutions thereof within the scope of the technology disclosed in the present disclosure, which shall be covered by the scope of protection of the present disclosure. Therefore, the scope of protection of the present disclosure shall be subject to the scope of protection of the claims.

1. An array substrate, comprising:
a base substrate comprising a first display region, a second display region, and a transition region disposed between the first display region and the second display region;
a first pixel unit disposed in the first display region, wherein the first pixel unit has a first aperture ratio;
a second pixel unit disposed in the second display region, wherein the second pixel region has a second aperture ratio; and
a third pixel unit disposed in the transition region, wherein the third pixel unit has a third aperture ratio;
wherein
the first aperture ratio is greater than the second aperture ratio;
in a direction pointing from the first display region towards the second display region, the first aperture ratio, the third aperture ratio, and the second aperture ratio progressively decrease.

2. The array substrate according to claim 1, comprising: a plurality of third pixel units, wherein the third aperture ratios of the plurality of third pixel units progressively decrease in the direction pointing from the first display region towards the second display region.

3. The array substrate according to claim 2, wherein the plurality of third pixel units are distributed in an array in the transition region.

4. The array substrate according to claim 3, wherein a row direction of the plurality of third pixel units is parallel to the direction pointing from the first display region towards the second display region; and different columns of the third pixel units correspond to a same rate of change; wherein
the rate of change corresponding to any one column of the third pixel units is: a difference between an aperture ratio of an adjacent column of pixel units and an aperture ratio of the any one column of the third pixel units; and
the adjacent column of pixel units is adjacent to the any one column of the third pixel units, and the adjacent column of pixel units and the any one column of the third pixel units are sequentially arranged in the direction pointing from the first display region towards the second display region.

5. The array substrate according to claim 3, wherein a row direction of the plurality of third pixel units is parallel to the direction pointing from the first display region towards the second display region; and at least two columns of the third pixel units correspond to different rates of change; wherein
the rate of change corresponding to any one column of the third pixel units is: a difference between an aperture ratio of an adjacent column of the pixel units and an aperture ratio of the any one column of the third pixel units;
the adjacent column pixel units are adjacent to the any one column of the third pixel units, and the adjacent column of the pixel units and the any one column of the third pixel units are sequentially arranged in the direction pointing from the first display region towards the second display region.

6. The array substrate according to claim 3, wherein
the row direction of the plurality of third pixel units is parallel to the direction pointing from the first display region towards the second display region, and the rate of change corresponding to the any one column of the third pixel units is less than or equal to 0.2;
the rate of change corresponding to the any one column of the third pixel units is: the difference between the aperture ratio of the adjacent column of the pixel units and the aperture ratio of the any one column of the third pixel units; and
the adjacent column of the pixel units is adjacent to the any one column of the third pixel units, and the adjacent column of the pixel units and the any one column of the third pixel units are sequentially arranged in the direction pointing from the first display region towards the second display region.

7. The array substrate according to claim 1, wherein the third pixel unit comprises a plurality of sub-pixels;
wherein in the direction pointing from the first display region towards the second display region, aperture ratios of the plurality of sub-pixels progressively decrease.

8. The array substrate according to claim 1, further comprising: a pixel defining layer disposed in the first display region, the second display region, and the transition region; wherein
the pixel defining layer of the first display region has an aperture corresponding to the first pixel unit, and an orthographic projection of an aperture in the pixel defining layer corresponding to any one pixel unit on the base substrate is within an orthographic projection of the any one pixel unit on the base substrate;
the pixel defining layer of the second display region has an aperture corresponding to the second pixel unit;
the pixel defining layer of the transition region has an aperture corresponding to the third pixel unit; and
an area of the aperture corresponding to the first pixel unit, an area of the aperture corresponding to the third pixel unit, and an area of the aperture corresponding to the second pixel unit progressively decrease in the direction pointing from the first display region towards the second display region.

9. The array substrate according to claim 1, wherein
the first display region and the transition region belong to a normal display region, and the second display region belongs to an under-display camera region; and
the under-display camera region is a display region configured to be matched with an under-display camera device, and the normal display region is a display region outside the under-display camera region.

10. The array substrate according to claim 1, wherein
the first display region belongs to a normal display region, and the second display region and the transition region belong to an under-display camera region; and
the under-display camera region is a display region configured to be matched with an under-display camera device, and the normal display region is a display region outside the under-display camera region.

11. The array substrate according to claim 1, wherein the transition region comprises a first transition region and a second transition region; wherein
the first display region and the first transition region belong to a normal display region, and the second display region and the second transition region belong to an under-display camera region;
wherein the under-display camera region is a display region configured to be matched with an under-display camera device, and the normal display region is a display region outside the under-display camera region.

12. The array substrate according to claim 9, wherein the normal display region is provided with a pixel defining layer having an aperture, the aperture in the pixel defining layer having a polygonal shape.

13. The array substrate according to claim 9, wherein the under-display camera region is provided with a pixel defining layer having an aperture, the aperture in the pixel defining layer having a circular shape or an elliptical shape.

14. The array substrate according to claim 9, wherein the under-display camera region is provided with a pixel defining layer having an aperture, at least a portion of the aperture in the pixel defining layer having a waterdrop shape.

15. The array substrate according to claim 1, wherein
any one of the pixel units of the first pixel unit, the second pixel unit, and the third pixel unit comprises an anode, a light-emitting layer, and a cathode arranged sequentially along a direction away from the base substrate; and
the array substrate further comprises the pixel defining layer disposed between the anode and the light-emitting layer.

16. A display panel, comprising: a cover plate, and an array substrate, wherein a portion of the array substrate other than the base substrate is disposed between the cover plate and the base substrate; and
the array substrate comprises:
a base substrate comprising a first display region, a second display region, and a transition region disposed between the first display region and the second display region;
a first pixel unit disposed in the first display region, wherein the first pixel unit has a first aperture ratio;
a second pixel unit disposed in the second display region, wherein the second pixel region has a second aperture ratio; and
a third pixel unit disposed in the transition region, wherein the third pixel unit has a third aperture ratio;
wherein
the first aperture ratio is greater than the second aperture ratio;
in a direction pointing from the first display region towards the second display region, the first aperture ratio, the third aperture ratio, and the second aperture ratio progressively decrease.

17. A display device comprising: a power supply assembly, and the display panel according to claim 16, wherein the power supply assembly is configured to supply power to the display panel.

18. A method for preparing the array substrate of claim 1, comprising:
preparing the first pixel unit, the second pixel unit, and the third pixel unit on the base substrate; wherein
the base substrate comprises the first display region, the second display region, and the transition region disposed between the first display region and the second display region;
the first pixel unit having the first aperture ratio is disposed in the first display region;
the second pixel unit having the second aperture ratio is disposed in the second display region;
the third pixel unit having the third aperture ratio is disposed in the transition region; and
in the direction pointing from the first display region towards the second display region, the first aperture ratio, the third aperture ratio and the second aperture ratio progressively decrease.

19. The method according to claim 18, further comprising:
forming a pixel defining material layer on the base substrate; and
patterning the pixel defining material layer to obtain the pixel defining layer; wherein
the pixel defining layer of the first display region has the aperture corresponding to the first pixel unit, the orthographic projection of the aperture in the pixel defining layer corresponding to any one pixel unit on the base substrate is disposed within the orthographic projection of the any one pixel unit on the base substrate;
the pixel defining layer of the second display region has the aperture corresponding to the second pixel unit;
the pixel defining layer of the transition region has the aperture corresponding to the third pixel unit; and
an area of the aperture corresponding to the first pixel unit, an area of the aperture corresponding to the third pixel unit, and an area of the aperture corresponding to the second pixel unit progressively decrease in the direction pointing from the first display region towards the second display region.

20. The method according to claim 19, wherein
preparing the first pixel unit, the second pixel unit, and the third pixel unit on the base substrate comprises:
forming the anode, the light-emitting layer, and the cathode of the pixel unit sequentially on the base substrate; and
forming the pixel defining material layer on the base substrate comprises:
forming the pixel defining material layer on the base substrate after the cathode is formed and before the light-emitting layer is formed.
